(19) United States
(12) Patent Application Publication
(10) Pub. No.: US 2026/0293617 A1
(43) Pub. Date: Sep. 24, 2026

(54) METHOD FOR MANUFACTURING SEMICONDUCTOR DEVICE USING PHOTOLITHOGRAPHY PROCESS

(71) Applicant: Inha University Research and Business Foundation, Incheon (KR)

(72) Inventors: Jin-Kyun LEE, Incheon (KR); Gayoung KIM, Hwaseong-si (KR)

(73) Assignee: Inha University Research and Business Foundation, Incheon (KR)

(21) Appl. No.: 19/573,769

(22) Filed: Mar. 20, 2026

(30) Foreign Application Priority Data
Mar. 20, 2025 (KR) 10-2025-0035878
Feb. 20, 2026 (KR) 10-2026-0031936

(51) Int. Cl. H10P 76/20; H10P 50/00

(52) U.S. Cl. CPC H10P 76/2041; H10P 50/73

(57) ABSTRACT

A method for manufacturing a semiconductor device includes forming an etching target layer on a substrate, forming a lower photoresist layer on the etching target layer, forming an upper photoresist layer on the lower photoresist layer, performing an exposure process to expose the upper photoresist layer and the lower photoresist layer, performing a first development process on the upper photoresist layer to form an upper photoresist pattern, and performing a second development process on the lower photoresist layer to form a lower photoresist pattern. The lower photoresist layer includes a first photoresist. The upper photoresist layer includes a second photoresist different from the first photoresist. The first development process and the second development process are performed using different developers.

### CROSS-REFERENCE TO RELATED APPLICATIONS

This U.S. non-provisional patent application claims priority under 35 U.S.C. § 119 of Korean Patent Application Nos. 10-2025-0035878, filed on Mar. 20, 2025, and 10-2026-0031936, filed on Feb. 20, 2026, the entire contents of which are hereby incorporated by reference.

### BACKGROUND

The present disclosure herein relates to a method for manufacturing a semiconductor device using a photolithography process.

This work was carried out with the support of Samsung Research Funding & Incubation Center for Future Technology (project number: SRFC-TA1703-51, research project name: Development of resist for extreme ultraviolet lithography (EUVL) and an application process).

Photolithography may include an exposure process and a development process. Performing the exposure process may include irradiating a resist layer with light of a specific wavelength to derive a chemical structure change of the resist layer. Performing the development process may include selectively removing an exposed portion or an unexposed portion of the resist layer by using a resolution difference between the exposed portion and the unexposed portion.

A semiconductor device may include wiring patterns constituting an integrated circuit. For example, the wiring patterns may electrically connect transistors or connect the transistors to an external device. The wiring patterns may include conductive lines extending in a horizontal direction parallel to a top surface of a substrate, and conductive contacts extending from a bottom surface of the conductive lines along a vertical direction perpendicular to the top surface of the substrate. The conductive lines and the conductive contacts may be formed using, for example, a dual damascene process. In this case, forming the conductive lines and the conductive contacts may include forming a line trench extending in the horizontal direction, forming a contact hole extending from a bottom surface of the line trench in the vertical direction, and forming a conductive layer filling the line trench and the contact hole. In this case, a photolithography process for forming the line trench and a photolithography process for forming the contact hole may be performed independently.

### SUMMARY

The present disclosure provides a method for manufacturing a semiconductor device, which is capable of forming wiring patterns including conductive lines extending in a horizontal direction and conductive contacts extending in a vertical direction by using a one-time exposure process.

The present disclosure also provides a method for manufacturing a semiconductor device, which is capable of reducing the difficulty and cost in manufacturing process for forming wiring patterns.

Issues to be addressed in the present disclosure are not limited to those described above and other issues unmentioned above will be clearly understood by those skilled in the art from the following description.

In an embodiment of the inventive concept, a method for manufacturing a semiconductor device may comprise forming an etching target layer on a substrate, forming a lower photoresist layer on the etching target layer, forming an upper photoresist layer on the lower photoresist layer, performing an exposure process to expose the upper photoresist layer and the lower photoresist layer, performing a first development process on the upper photoresist layer to form an upper photoresist pattern, and performing a second development process on the lower photoresist layer to form a lower photoresist pattern. The lower photoresist layer may include a first photoresist. The upper photoresist layer may include a second photoresist different from the first photoresist. The first development process and the second development process may be performed using different developers.

In an embodiment of the inventive concept, a method for manufacturing a semiconductor device may comprise forming a lower photoresist layer on a substrate, forming an upper photoresist layer on the lower photoresist layer, performing an exposure process to expose the upper photoresist layer and the lower photoresist layer, performing a first development process on the upper photoresist layer to form an upper photoresist pattern, and performing a second development process on the lower photoresist layer to form a lower photoresist pattern. The lower photoresist layer may include a first photoresist not containing fluorine. The upper photoresist layer may include a second photoresist containing fluorine. The first development process may be performed using a fluorine-based developer.

In an embodiment of the inventive concept, a method for manufacturing a semiconductor device may comprise forming an etching target layer on a substrate, forming a lower photoresist layer on the etching target layer, forming an upper photoresist layer on the lower photoresist layer, performing a single exposure process to expose the upper photoresist layer and the lower photoresist layer, performing a first development process on the upper photoresist layer to form an upper photoresist pattern, performing a second development process on the lower photoresist layer to form a lower photoresist pattern, and etching the etching target layer using the upper and lower resist patterns as etching masks. The upper photoresist layer may include negative photoresist containing fluorine. The lower photoresist layer may include positive photoresist not containing fluorine. The first development process and the second development process may be performed using different developers.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart showing a method for manufacturing a semiconductor device according to some embodiments of the present inventive concept;

FIGS. 2 to 7 are cross-sectional views showing a method for manufacturing a semiconductor device according to some embodiments of the inventive concept;

FIGS. 8 to 15 are images showing atomic force microscope (AFM) analysis results of resist patterns formed under different exposure dose conditions according to example 1; and

FIGS. 16 to 20 are images showing AFM analysis results of multi-layer resist patterns formed under different exposure dose conditions according to example 2.

### DETAILED DESCRIPTION

The embodiments of the present disclosure will now be described with reference to the accompanying drawings for sufficiently understating a configuration and effects of the inventive concept. However, the inventive concept is not limited to the following embodiments and may be embodied in different ways, and various modifications may be made thereto. The embodiments are just given to provide complete disclosure of the inventive concept and to provide thorough understanding of the inventive concept to those skilled in the art. It will be understood to those skilled in the art that the inventive concept may be performed in a certain suitable environment.

The terminology used herein is for the purpose of describing embodiments and is not intended to limit the scope of the present inventive concept. As used herein, the singular forms “a”, “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Unless otherwise specified in the present specification, an alkyl group includes a linear, branched, or cyclic monovalent saturated hydrocarbon group.

In the present specification, an alkylene group includes a linear, branched, or cyclic divalent saturated hydrocarbon group.

In the present specification, a fluoroalkyl group is an alkyl group in which at least one hydrogen atom is substituted by a fluorine atom, a fluoroalkylene group is an alkylene group in which at least one atom is substituted by a fluorine atom, a fluoroaryl group is an aryl group in which at least one atom is substituted by a fluorine atom, and a fluorinated alkoxy group is an alkoxy group in which at least one atom is substituted by a fluorine atom.

In the present specification, “a hydrocarbon group is substituted by” means that at least one of hydrogen atoms of a hydrocarbon group is substituted by a functional group or atoms other than the hydrogen atoms.

Unless otherwise defined in the present specification, a case where a chemical bond is not drawn in Chemical Formula where supposed to be given may mean that hydrogen atoms are bonded at the position.

Hereinafter, embodiments of the inventive concept will be described in detail with reference to the accompanying drawings. Same reference numerals on drawings are used to designate same elements, and repeated descriptions of the same components will be omitted.

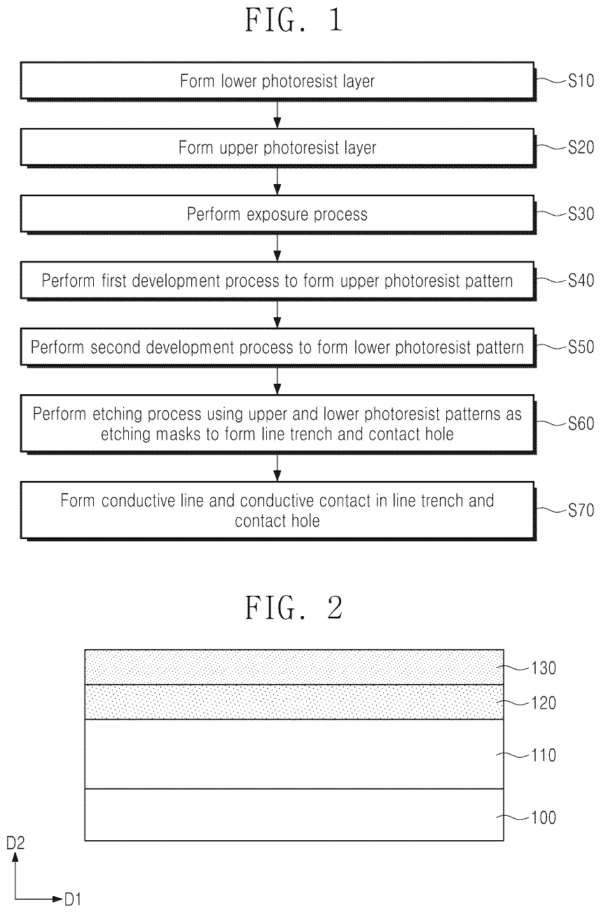

FIG. 1 is a flowchart showing a method for manufacturing a semiconductor device according to some embodiments of the present inventive concept. FIGS. 2 to 7 are cross-sectional views showing a method for manufacturing a semiconductor device according to some embodiments of the inventive concept.

Referring to FIGS. 1 and 2, an etching target layer 110 may be formed on a substrate 100. The substrate 100 may be a semiconductor substrate, for example, a silicon substrate, a germanium substrate, or a silicon/germanium substrate. The etching target layer 110 may include at least one selected from a semiconductor material, a conductive material, or an insulation material, or a combination thereof. According to some embodiments, the etching target layer 110 may include an insulation material. The etching target layer 110 may be formed with a single layer, or include a plurality of layers laminated on the substrate 100.

A lower photoresist layer 120 may be formed on the etching target layer 110 (S10). The lower photoresist layer 120 may include a first photoresist. The first photoresist may be positive photoresist, and does not contain fluorine. According to some embodiments, the first photoresist may include a polymer including a repeating unit represented by Chemical Formula 1.

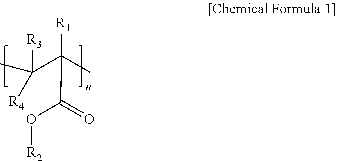

In Chemical Formula 1, R1, R2, R3, and R4 are each independently hydrogen or an alkyl group having 1 to 10 carbon atoms, and n is an integer of 2 to 10,000.

For example, the first photoresist may include a polymer represented by Chemical Formula 1-1.

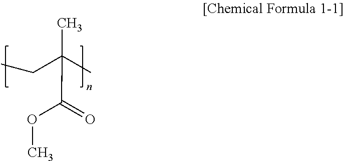

In Chemical Formula 1-1, n is an integer of 2 to 10,000.

Forming the lower photoresist layer 120 may include, for example, applying the first photoresist on the etching target layer 110 using a spin coating method. Forming the lower photoresist layer 120 may further include, for example, performing a heat treatment process (e.g., a soft baking process) on the applied first photoresist.

An upper photoresist layer 130 may be formed on the lower photoresist layer 120 (S20). The upper photoresist layer 130 may include a second photoresist different from the first photoresist. The second photoresist may be negative photoresist, and contain fluorine. According to some embodiments, the second photoresist may include a copolymer represented by Chemical Formula 2, or organometallic oxide containing fluorine.

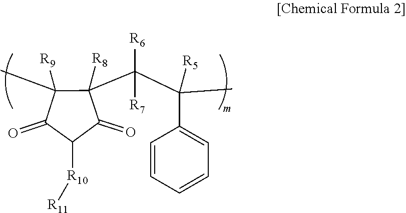

In Chemical Formal 2, R5, R6, R7, R8, and R9 are each independently hydrogen or an alkyl group having 1 to 10 carbon atoms, R10 is an single bond or an alkylene group having 1 to 10 carbon atoms, R11 is a fluoroalkyl group having 1 to 20 carbon atoms, a fluoroalkyl ether fluoroalkyl group having 2 to 20 carbon atoms, a fluoroalkyl ether fluoroalkylene ether fluoroalkyl group having 3 to 20 carbon atoms, or a fluoroaryl group having 6 to 20 carbon atoms, and m is an integer of 2 to 10,000.

For example, the second photoresist may include a copolymer represented by Chemical Formula 2-1.

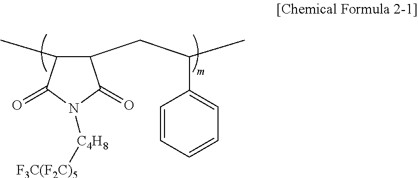

In Chemical Formula 2-1, n is an integer of 2 to 10,000.

For another example, the second photoresist may include organotin oxide containing fluorine.

Forming the upper photoresist layer 130 may include, for example, applying the second photoresist on the lower photoresist layer 120 using a spin coating method. Forming the upper photoresist layer 130 may further include, for example, performing a heat treatment process (e.g., a soft baking process) on the applied second photoresist.

Since the lower photoresist layer 120 includes the first photoresist not containing fluorine, dissolution of the lower photoresist layer 120 by fluorine-based solution may be limited. Accordingly, while the second photoresist containing fluorine is applied on the lower photoresist layer 120, the lower photoresist layer 120 may not be damaged. Accordingly, multi-layered photoresist stack including the lower photoresist layer 120 and the upper photoresist layer 130 may be easily formed.

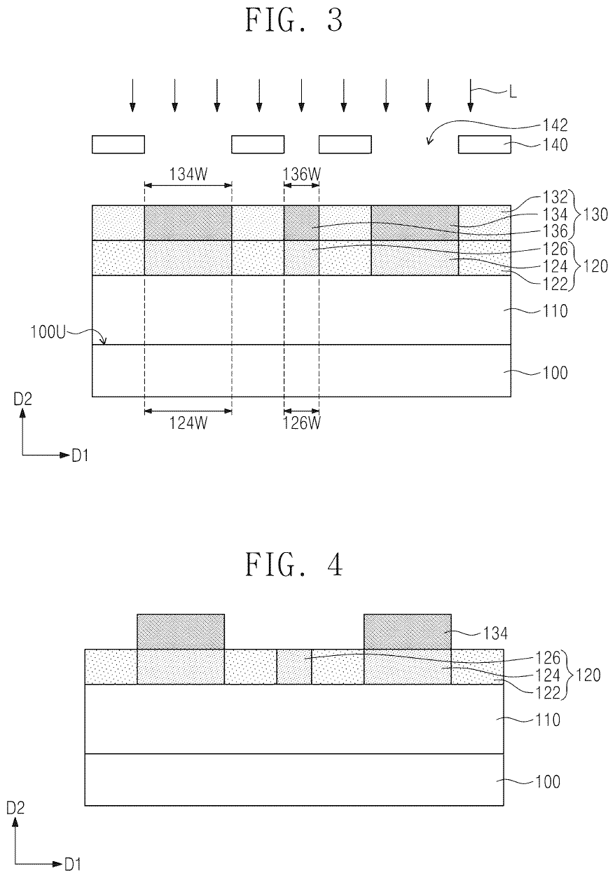

Referring to FIGS. 1 and 3, an exposure process may be performed on the stacked upper and lower photoresist layers 130 and 120 (S30). The exposure process may include irradiating the upper and lower photoresist layers 130 and 120 with light L. The light L may be ultraviolet rays (for example, ultraviolet rays having a wavelength of 365 nm), deep ultraviolet rays (for example, ultraviolet rays having a wavelength of 130 nm to 280 nm), extreme ultraviolet rays (for example, ultraviolet rays having a wavelength of 10 nm to 124 nm, particularly, a wavelength of 13.0 nm to 13.9 nm, and more particularly, a wavelength of 13.4 nm to 13.6 nm), or electron beams. For example, the exposure process may include aligning a photomask 140 on the upper and lower photoresist layers 130 and 120, and irradiating the upper and lower photoresist layers 130 and 120 with the light L (e.g., deep ultraviolet rays or extreme ultraviolet rays) through the photomask 140. For another example, the exposure process may include irradiating and scanning the upper and lower photoresist layers 130 and 120 with the light L (e.g., electron beams) using an electron beam lithography device. The exposure process may be a single exposure process.

The upper photoresist layer 130 may include a first exposed portion 134 and a second exposed portion 136 that are exposed to the light L, and a first unexposed portion 132 that is not exposed to the light L. For example, the light L may be irradiated on the first and second exposed portions 134 and 136 through an opening 142 of the photomask 140, and the light L may be blocked by the photomask 140 and not irradiated on the first unexposed portion 132.

The first exposed portion 134 and the second exposed portion 136 may be spaced apart from each other along a first direction D1 parallel to a top surface 100U of the substrate 100. The first direction D1 may be referred to as a horizontal direction. According to some embodiments, the first exposed portion 134 may include a pair of first exposed portions 134 spaced apart from each other in the first direction D1. The second exposed portion 136 may be disposed between the pair of first exposed portions 134, and be spaced apart from the pair of first exposed portions 134 along the first direction D1. A width 134W of the first exposed portion 134 (for example, a width of each of the pair of first exposed portions 134) along the first direction D1 may be greater than a width 136W of the second exposed portion 136 along the first direction D1

The lower photoresist layer 120 may include a third exposed portion 124 and a fourth exposed portion 126 that are exposed to the light L, and a second unexposed portion 122 that is not exposed to the light L. For example, the light L may be irradiated on the third and fourth exposed portions 124 and 126 through the opening 142 of the photomask 140, and the light L may be blocked by the photomask 140 and not irradiated on the second unexposed portion 122.

Since the upper and lower photoresist layers 130 and 120 are exposed by the single exposure process, the third exposed portion 124 may vertically overlap with the first exposed portion 134 along a second direction D2 that is perpendicular to the top surface 100U of the substrate 100, and the fourth exposed portion 126 may vertically overlap with the second exposed portion 136 along the second direction D2. The second unexposed portion 122 may vertically overlap with the first unexposed portion 132 along the second direction D2. The second direction D2 may be referred to as a vertical direction.

The third exposed portion 124 and the fourth exposed portion 126 may be spaced apart from each other along the first direction D1. According to some embodiments, the third exposed portion 124 may include a pair of third exposed portions 124 spaced apart from each other in the first direction D1. The fourth exposed portion 126 may be disposed between the pair of third exposed portions 124, and be spaced apart from the pair of third exposed portions 124 along the first direction D1. A width 124W of the third exposed portion 124 (for example, a width of each of the pair of third exposed portions 124) along the first direction D1 may be greater than a width 126W of the fourth exposed portion 126 along the first direction D1.

Since the upper photoresist layer 130 include the second photoresist (e.g., negative photoresist), the solubility of the first and the second exposed portions 134 and 136 of the upper photoresist layer 130 may be reduced in comparison to the first unexposed portion 132 of the upper photoresist layer 130.

The solubility of the second exposed portion 136 with the relatively small width and the solubility of the first exposed portion 134 with the relatively large width may be adjusted according to an exposure dose in the exposure process. An exposure dose required for the second exposed portion 136 with the relatively small width to have a prescribed solubility may be greater than an exposure dose required for the first exposed portion 134 with the relatively large width to have the prescribed solubility. For example, when the first exposed portion 134 is exposed at the same exposure dose as the second exposed portion 136, the solubility of the first exposed portion 134 may be lower than that of the second exposed portion 136. Accordingly, the exposure dose in the exposure process may be adjusted so that the first exposed portion 134 having the relatively larger width has a lower solubility than the second exposed portion 136 having the relatively smaller width.

Since the lower photoresist layer 120 includes the first photoresist (e.g., positive photoresist), the solubility of the third and fourth exposed portions 124 and 126 of the lower photoresist layer 120 may be increased in comparison to the second unexposed portion 122 of the lower photoresist layer 120.

Referring to FIGS. 1 and 4, the photomask 140 may be removed after the exposure process. A first development process may be performed on the upper photoresist layer 130 to form an upper photoresist pattern 134 (S40).

The first development process may include removing the first unexposed portion 132 of the upper photoresist layer 130. The first exposed portion 134 may have a smaller solubility than the second exposed portion 136, and the first development process may further include removing the second exposed portion 136. The first unexposed portion 132 and the second exposed portion 136 of the upper photoresist layer 130 may be selectively removed by the first development process, and the upper photoresist pattern 134 may include the first exposed portion 134 of the upper photoresist layer 130.

The first development process may be performed using a fluorine-based developer. The fluorine-based developer may include, for example, hydrofluoroether (HFE) and/or perfluorocarbon (PFC). Since the upper photoresist layer 130 includes the second photoresist containing fluorine, the upper photoresist layer 130 may have solubility in the fluorine-based developer. The lower photoresist layer 120 may include the first photoresist not containing fluorine, and thus dissolution of the lower photoresist layer 120 by the fluorine-based developer may be limited. Accordingly, the lower photoresist layer 120 may not be removed by the first development process.

The first unexposed portion 132 and the second exposed portion 136 of the upper photoresist layer 130 may be selectively removed by the first development process, and thus the second unexposed portion 122 and the fourth exposed portion 126 of the lower photoresist layer 120 may be exposed to the outside.

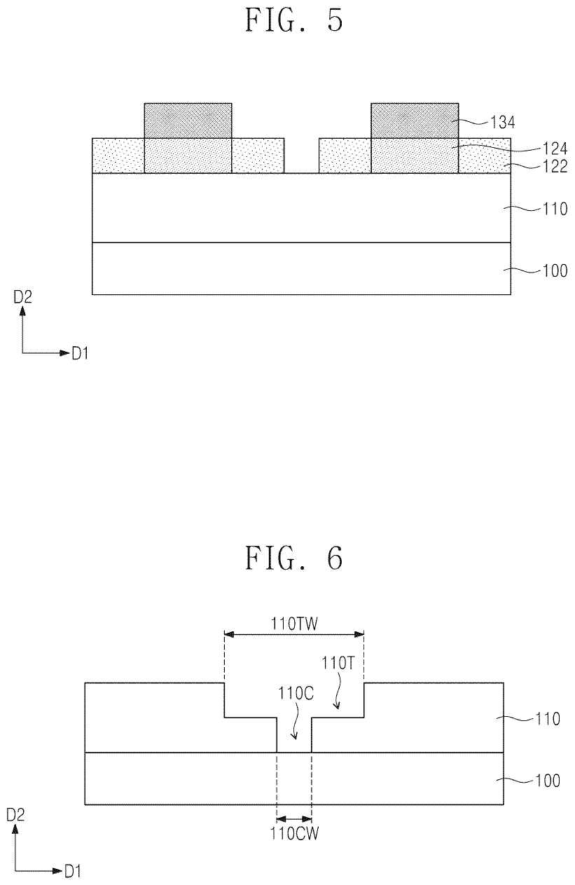

Referring to FIGS. 1 and 5, a second development process may be performed on the lower photoresist layer 120 to form a lower photoresist pattern 122 and 124 (S50).

The second development process may include removing the fourth exposed portion 126 of the lower photoresist layer 120. The third exposed portion 124 of the lower photoresist layer 120 may be protected by the upper photoresist pattern 134 and not be removed by the second development process. The fourth exposed portion 126 of the lower photoresist layer 120 may be selectively removed by the second development process, and the lower photoresist pattern 122 and 124 may include the second unexposed portion 122 and the third exposed portion 124 of the lower photoresist layer 120.

The second development process may be performed using a developer different from that in the first development process. The developer in the second development process may include, for example, a standard aqueous base solution (e.g., tetramethylammonium hydroxide (TMAH) aqueous solution), a ketone-based organic solvent such as methyl isobutyl ketone (MIBK), and/or an alcohol-based organic solvent such as isopropanol (IPA). Since the upper photoresist layer 130 includes the second photoresist containing fluorine, the upper photoresist pattern 134 may have hydrophobicity, and thus the upper photoresist pattern 134 may have a low solubility in an aqueous solution-based developer (e.g., TMAH). In addition, since the upper photoresist layer 130 includes the negative second photoresist, the upper photoresist pattern 134 may have a low solubility in an organic solvent-based developer (e.g., MIBK and/or IPA). Accordingly, the upper photoresist pattern 134 may have a low solubility in the developer in the second development process, and not be removed in the second development process.

The fourth exposed portion 126 of the lower photoresist layer 120 may be selectively removed by the second development process, and thus a portion of the etching target layer 110 may be exposed to the outside.

Referring to FIGS. 1 and 6, an etching process in which the upper photoresist pattern 134 and the lower photoresist pattern 122 and 124 are used as etching masks may be performed, and thus a line trench 110T and a contact hole 110C may be formed in the etching target layer 110 (S60). The etching process may include, for example, a wet etching or dry etching process. The line trench 110T may have a line shape extending in the first direction D1, and the contact hole 110C may extend from a bottom surface of the line trench 110T towards the substrate 100 along the second direction D2. A width 110TW of the line trench 110T along the first direction D1 may be greater than a width 110CW of the contact hole 110C along the first direction D1.

After the line trench 110T and the contact hole 110C are formed, the upper photoresist pattern 134 and the lower photoresist pattern 122 and 124 may be removed. The upper photoresist pattern 134 and the lower photoresist pattern 122 and 124 may be removed by, for example, an ashing process and/or a strip process.

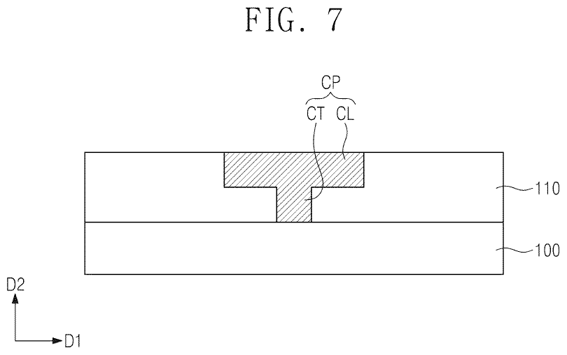

Referring to FIGS. 1 and 7, a conductive line CL and a conductive contact CT may be formed to fill the line trench 110T and the contact hole 110C, respectively (S70). Forming the conductive line CL and the conductive contact CT may include forming a conductive layer filling the line trench 110T and the contact hole 110C on the etching target layer 110, and planarizing the conductive layer until a top surface of the etching target layer 110 is exposed. The planarizing the conductive layer may be performed by, for example, an etch-back process or a chemical mechanical polishing process. The conductive line CL and the conductive contact CT may be formed substantially simultaneously using, for example, a dual damascene method. The conductive line CL and the conductive contact CT may be referred to as a wiring pattern CP, and the wiring pattern CP may constitute an integrated circuit of a semiconductor device.

According to the inventive concept, the lower photoresist layer 120 and the upper photoresist layer 130 including different materials may be sequentially laminated on the etching target layer 110, and the single exposure process may be performed on the lower photoresist layer 120 and the upper photoresist layer 130. The first development process may be performed on the upper photoresist layer 130 to form the upper photoresist pattern 134, and the second development process may be performed on the lower photoresist layer 120 to form the lower photoresist pattern 122 and 124. The etching target layer 110 may be etched using the upper photoresist pattern 134 and the lower photoresist pattern 122 and 124 as the etching masks, and thus the line trench 110T extending in the first direction D1 (e.g., the horizontal direction) and the contact hole 110C extending from the bottom surface of the line trench 110T in the second direction D2 (e.g., the vertical direction) may be substantially simultaneously formed in the etching target layer 110. Accordingly, the line trench 110T and the contact hole 110C having different shapes may be easily formed by one-time exposure process, and thus the difficulty and the cost of the manufacturing process for forming the line trench 110T and the contact hole 110C may be reduced. Then, the wiring pattern CP may be formed to fill the line trench 110T and the contact hole 110C using the dual damascene method. The wiring pattern CP may include the conductive line CL filling the line trench 110T and extending in the first direction D1 (e.g., the horizontal direction), and the conductive contact CT filling the contact hole 110C and extending in the second direction D2 (e.g., the vertical direction).

Accordingly, a method for manufacturing a semiconductor device, which is capable of forming the wiring pattern including the conductive line extending in the horizontal direction and the conductive contact extending in the vertical direction using one-time exposure process, and reducing the difficulty and the cost of the manufacturing process for forming the wiring pattern.

### [Example 1] Evaluation of Electron Beam Lithography of Photoresist Including Copolymer P(1-(5,5,6,6,7,7,8,8,9,9,10,10,10-Tridecafluorodecyl)-1H-pyrrole-2,5-dione-alt-Styrene) (P(RFMI6-St)) Represented in Chemical Formula 2-1

A resist composition solution with a concentration of 4 wt/vol % was manufactured by dissolving P(RFMI6-St) (Mw~13K, PDI (polydispersity index) 1.2, RSC Advances, 2021, 11, 1517, ACS Applied Materials & Interfaces, 2025, 17, 70920) in PF-7600 (purchased from 3M). The resist composition solution was spin-coated on a silicon wafer at 2,000 rpm for 60 seconds, and then heated at 100° C. for 1 minute to form a resist thin film with a thickness of about 115 nm. Electron beams of 50 μC/cm² to 1,500 μC/cm² was irradiated on the resist thin film under an acceleration voltage of 80 keV. Then a development process using the PF-7600 (3M) developer was performed for 30 seconds to form negative resist patterns having 100 nm×100 nm square shape and 300 nm×300 nm square shape. Steps of the 100 nm×100 nm square pattern and 300 nm×300 nm square pattern formed at different exposure doses were compared through an atomic force microscope (AFM) analysis.

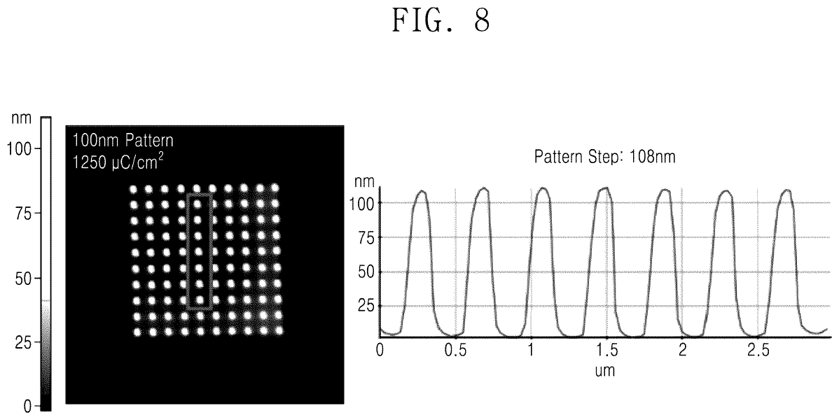

FIGS. 8 to 15 are images showing AFM analysis results of resist patterns formed under different exposure dose conditions according to example 1. In FIGS. 8 to 15, a 2D image of each resist pattern is on the left, and a cross-sectional profile image of each resist pattern is on the right.

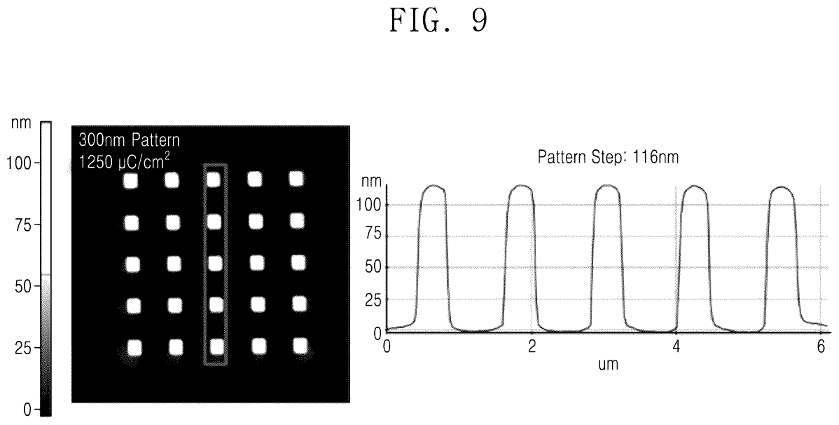

Referring to FIGS. 8 and 9, under an exposure condition of 1250 μC/cm², the step of 100 nm×100 nm square pattern (FIG. 8) was measured as 108 nm, and the step of 300 nm×300 nm square pattern (FIG. 9) was measured as 116 nm. Namely, it may be confirmed that under the exposure condition of 1250 μC/cm², the step of 100 nm×100 nm square pattern and the step of 300 nm×300 nm square pattern are similar.

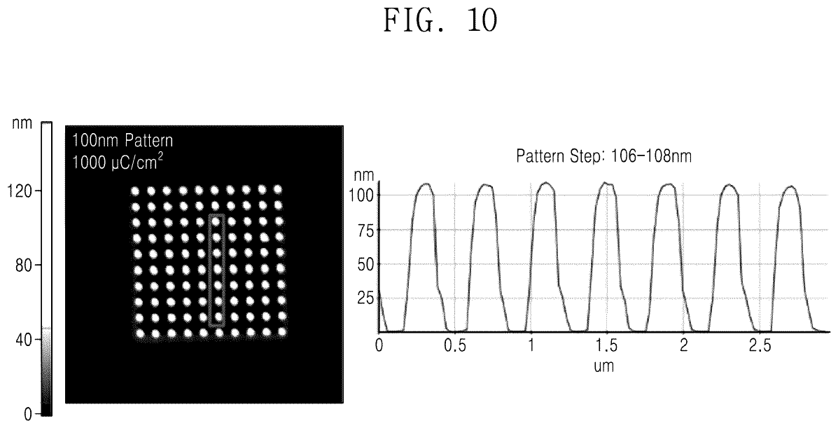

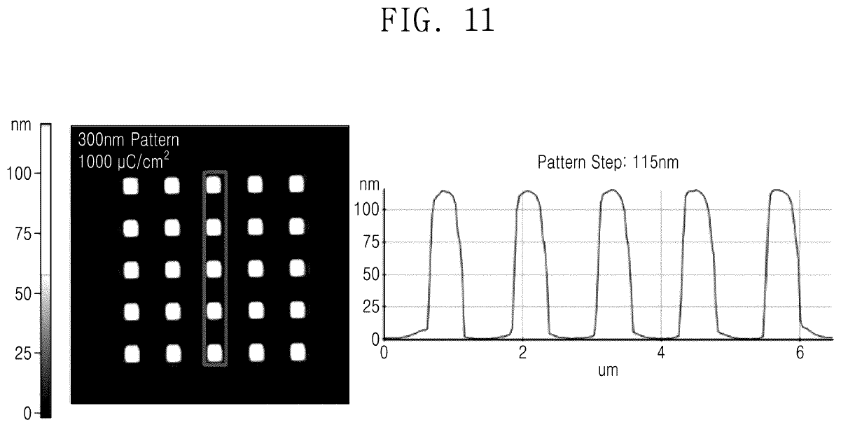

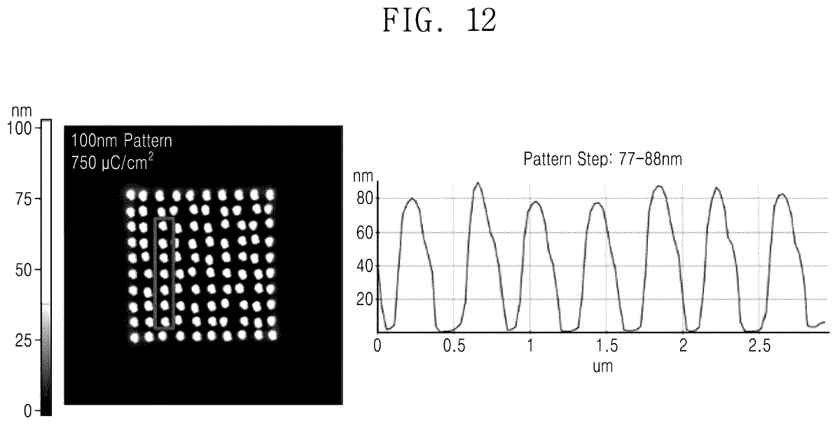

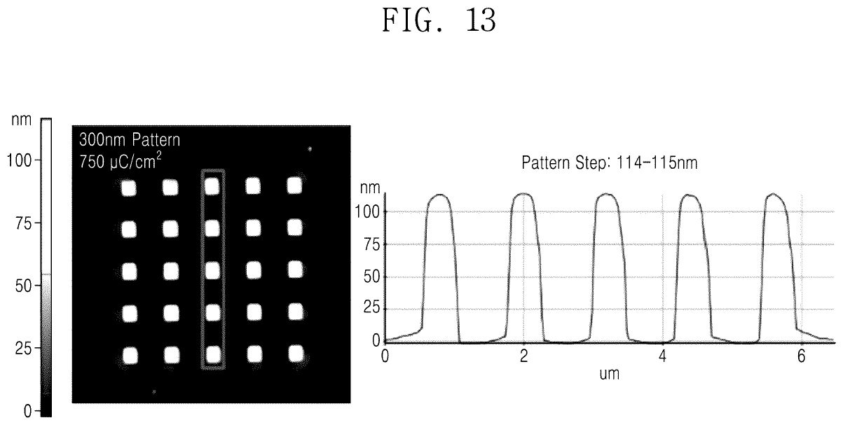

Referring to FIGS. 10 and 11, under an exposure condition of 1,000 μC/cm², the step of 100 nm×100 nm square pattern (FIG. 10) was measured as 106 nm to 108 nm, and the step of 300 nm×300 nm square pattern (FIG. 11) was measured as 115 nm. Namely, it may be confirmed that under the exposure condition of 1,000 μC/cm², the step of 100 nm×100 nm square pattern and the step of 300 nm×300 nm square pattern are similar.

Referring to FIGS. 12 and 13, under an exposure condition of 750 μC/cm², the step of 100 nm×100 nm square pattern (FIG. 12) was measured as 77 nm to 88 nm, and the step of 300 nm×300 nm square pattern (FIG. 13) was measured as 114 nm to 115 nm. Namely, it may be confirmed that under the exposure condition of 750 μC/cm², a difference between the step of 100 nm×100 nm square pattern and the step of 300 nm×300 nm square pattern is greater than 20 nm.

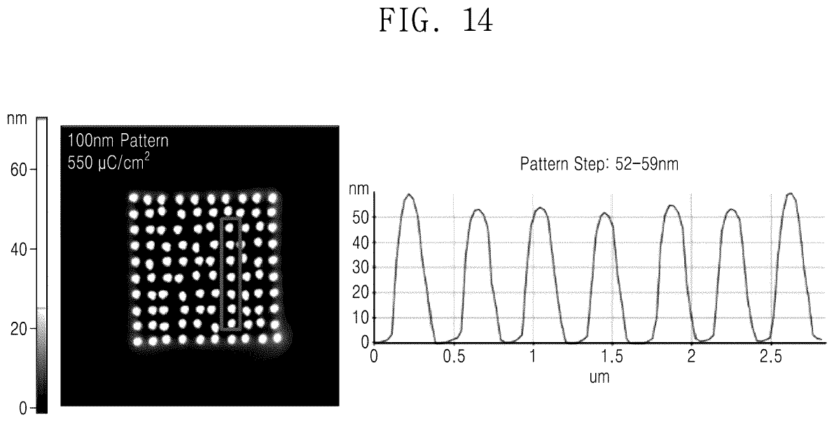

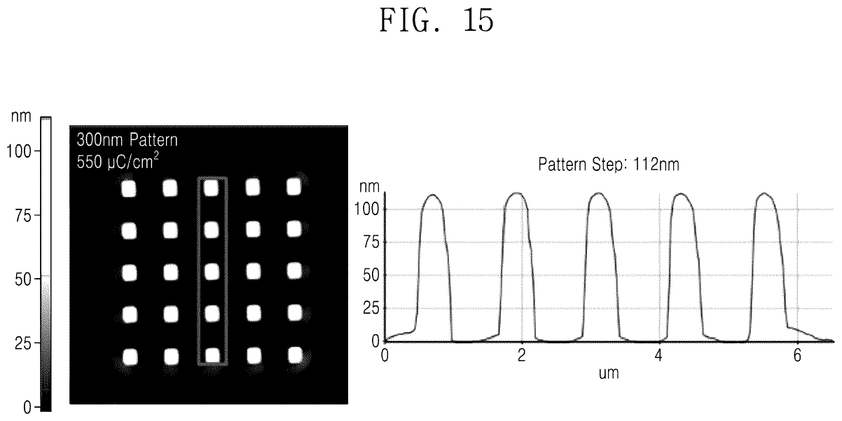

Referring to FIGS. 14 and 15, under an exposure condition of 550 μC/cm², the step of 100 nm×100 nm square pattern (FIG. 14) was measured as 52 nm to 59 nm, and the step of 300 nm×300 nm square pattern (FIG. 15) was measured as 112 nm. Namely, it may be confirmed that under the exposure condition of 550 μC/cm², a difference between the step of 100 nm×100 nm square pattern and the step of 300 nm×300 nm square pattern is greater than 50 nm.

Referring to FIGS. 8 to 15, it may be confirmed that the step of 100 nm×100 nm square pattern is reduced under the exposure condition of 750 μC/cm² or less, and the step of 300 nm×300 nm square pattern is maintained at a certain level under the exposure condition of 750 μC/cm² or less. From this, it may be confirmed that the smaller the size of the resist pattern, an exposure dose (i.e., an exposure dose for the resist pattern to have a prescribed solubility) required for forming the resist pattern increases. Accordingly, as described with reference to FIGS. 1 and 3, by adjusting the exposure dose of the exposure process, the first exposed portion 134 with the relatively large width may have a lower solubility than the second exposed portion 136 with the relatively small width.

### [Example 2] Evaluation of Electron Beam Lithography for a Multi-Layer Photoresist Thin Film in which a Lower Photoresist Layer Including Polymer (PMMA) Represented in Chemical Formula 1-1 and an Upper Photoresist Layer Including Copolymer (P(RFMI6-St)) Represented in Chemical Formula 2-1 are Laminated

A first resist composition solution obtained by appropriately diluting poly(methyl methacrylate) (PMMA), Mw~950K (purchased from MicroChem)) in chlorobenzene was spin-coated on a silicon wafer at 1,500 rpm for 60 seconds, and then heated at 100° C. for 1 minute to form a lower resist thin film with a thickness of about 80 nm to about 100 nm.

A second resist composition solution obtained by dissolving P(RFMI6-St) (Mw~13K, PDI 1.2) in PF-7600 at a concentration of 3.8 wt/vol % was spin-coated on the lower resist thin film at 4,000 rpm for 60 seconds, and then heated at 100° C. for 1 minute to form an upper resist thin film with a thickness of about 80 nm to about 100 nm.

Electron beams of 50 μC/cm² to 1,500 μC/cm² was irradiated on the multi-layer resist thin film including the upper resist thin film and the lower resist thin film under an acceleration voltage of 80 keV. Then a first development process using PF-7600 developer was performed for 20 seconds to form a negative upper resist pattern. During the first development process, a sonication process was also performed together. Then a second development process using, as a developer, a mixed solvent of methyl isobutyl ketone (MIBK) and isopropanol (IPA) (volume ratio, MIBK:IPA=1:2 or 1:10) was performed for 30 seconds to form a positive lower resist pattern. Then an AFM analysis was performed on the multi-layer resist pattern including the negative upper resist pattern and the positive lower resist pattern.

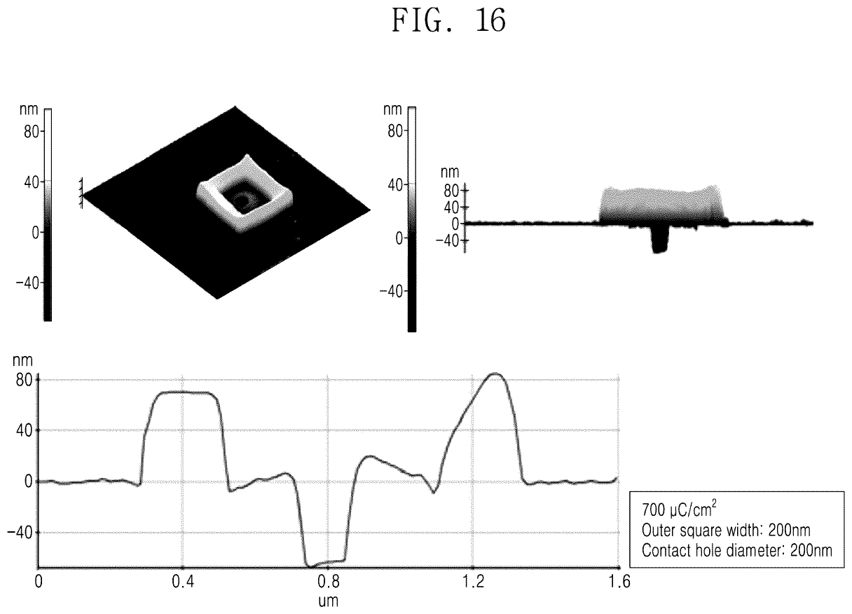

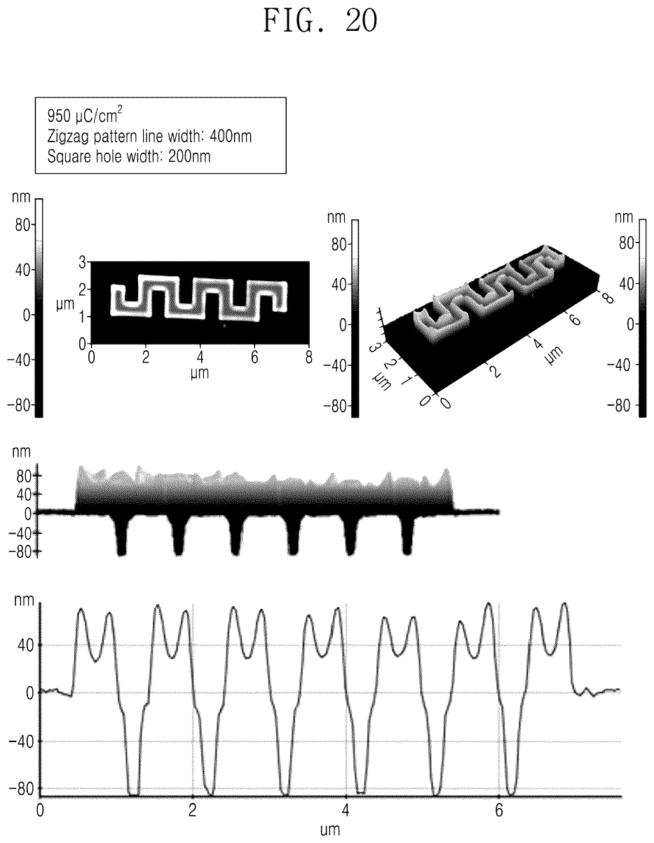

FIGS. 16 to 20 are images showing AFM analysis results of multi-layer resist patterns formed under different exposure dose conditions according to example 2. In FIGS. 16 to 19, a 3D image of the multi-layer resist pattern is at the upper left, a 2D cross-sectional image of the multi-layer resist pattern is at the upper right, and a cross-sectional profile image of the multi-layer resist pattern is at the lower portion. In FIG. 20, a 2D and 3D image of the multi-layer resist pattern is at the upper portion, a 2D cross-sectional image of the multi-layer resist pattern is at the intermediate portion, and a cross-sectional profile image of the multi-layer resist pattern is at the lower portion.

Referring to FIG. 16, it may be confirmed that a single exposure process was performed, under an exposure condition of 700 μC/cm², to form the multi-layer resist pattern including an upper resist pattern having a square ring shape with a line width of 200 nm and a lower resist pattern including a contact hole with a diameter of 200 nm.

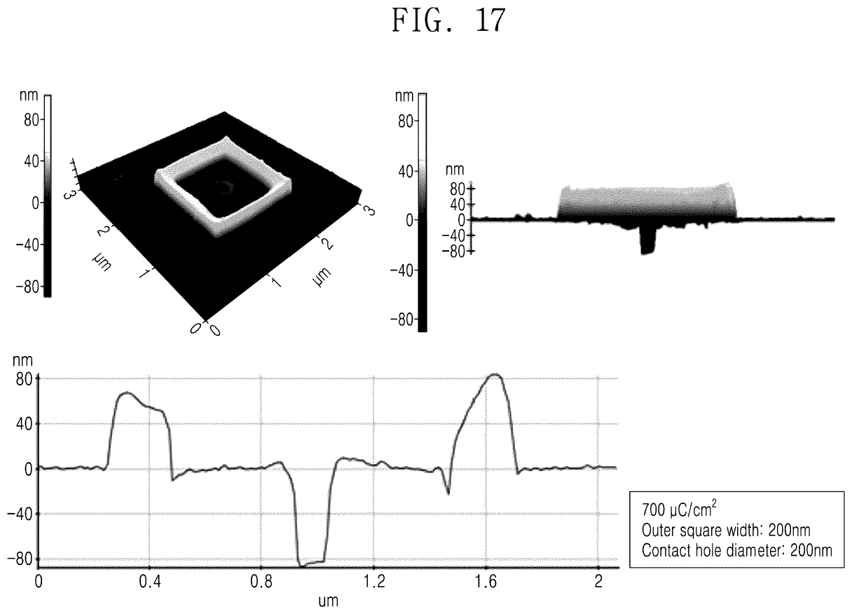

Referring to FIG. 17, it may be confirmed that a single exposure process was performed, under an exposure condition of about 700 μC/cm², to form the multi-layer resist pattern including an upper resist pattern having a square ring shape with a line width of 200 nm and a lower resist pattern including a contact hole with a diameter of 200 nm.

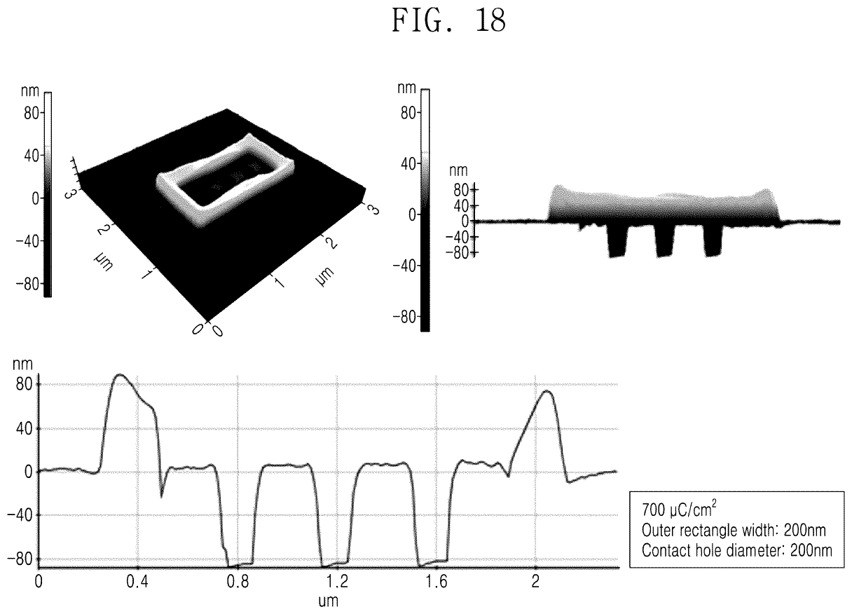

Referring to FIG. 18, it may be confirmed that a single exposure process was performed, under an exposure condition of about 700 μC/cm², to form the multi-layer resist pattern including an upper resist pattern having a rectangular ring shape with a line width of 200 nm and a lower resist pattern including a contact hole with a diameter of 200 nm.

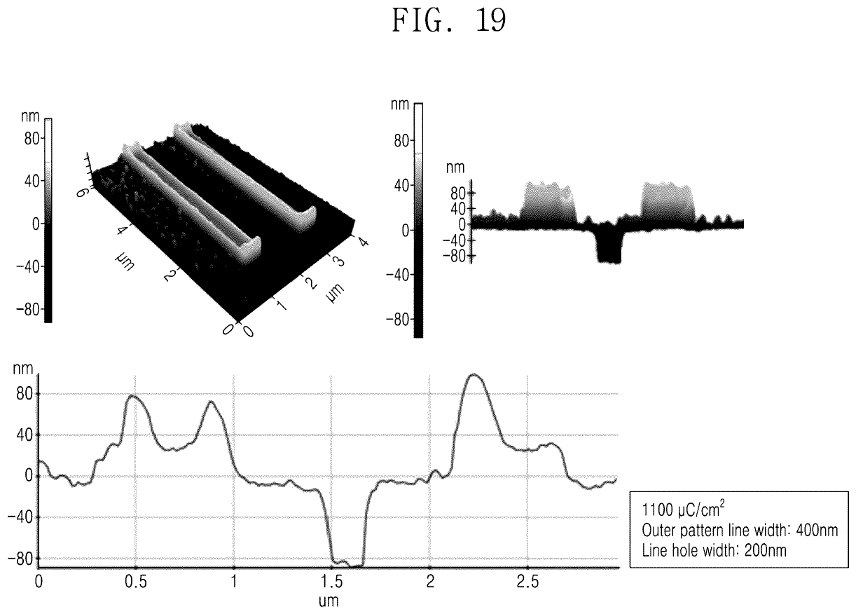

Referring to FIG. 19, it may be confirmed that a single exposure process was performed, under an exposure condition of 1,100 μC/cm², to form the multi-layer resist pattern including an upper resist pattern having line patterns with a line width of 400 nm and a lower resist pattern including a line hole with a width of 200 nm.

Referring to FIG. 20, it may be confirmed that a single exposure process was performed, under an exposure condition of 950 μC/cm², to form the multi-layer resist pattern including an upper resist pattern having a zigzag line pattern with a line width of 400 nm and a lower resist pattern including square holes with a width of 200 nm.

Referring to FIGS. 16 to 20, it may be confirmed that a single exposure process may be performed, under an exposure condition of 700 μC/cm² to 1,100 μC/cm², to form the multi-layer resist pattern having various shapes.

According to the inventive concept, a lower photoresist layer and an upper photoresist layer having different materials may be sequentially laminated on an etching target layer. The lower photoresist layer may include a positive photoresist not containing fluorine, and the upper photoresist layer may include negative photoresist containing fluorine. A single exposure process may be performed on the lower photoresist layer and the upper photoresist layer, a first development process may be performed on the upper photoresist layer to form an upper photoresist pattern, and a second development process may be performed on the lower photoresist layer to form a lower photoresist pattern. The first development process and the second development process may be performed using different developers. An etching process using the upper photoresist pattern and the lower photoresist pattern as etching masks may be performed to substantially simultaneously form a line trench and a contact hole having different shapes in the etching target layer. Namely, the line trench and the contact hole having different shapes may be easily formed by one-time exposure process, and thus the difficulty and cost of a manufacturing process for forming the line trench and contact hole may be reduced. Then, wiring patterns may be formed to fill the line trench and the contact hole.

Accordingly, a method for manufacturing a semiconductor device, which is capable of forming the wiring patterns filling the line trench and the contact hole using the one-time exposure process, and reducing the difficulty and cost of the manufacturing process for forming the wiring patterns, may be provided.

The above-described description about the embodiments of the inventive concept provides examples for explaining the inventive concept. It is apparent that the inventive concept is not limited to the foregoing embodiments but various changes and modifications can be made by one ordinary skilled in the art within the technical spirit of the inventive concept in combination with the above embodiments.

What is claimed is:

1. A method for manufacturing a semiconductor device, the method comprising:
forming an etching target layer on a substrate;
forming a lower photoresist layer on the etching target layer;
forming an upper photoresist layer on the lower photoresist layer;
performing an exposure process to expose the upper photoresist layer and the lower photoresist layer;
performing a first development process on the upper photoresist layer to form an upper photoresist pattern; and
performing a second development process on the lower photoresist layer to form a lower photoresist pattern, wherein
the lower photoresist layer includes a first photoresist, and the upper photoresist layer includes a second photoresist different from the first photoresist, and
the first development process and the second development process are performed using different developers.

2. The method of claim 1, wherein
the upper photoresist layer includes a first exposed portion, a second exposed portion, and a first unexposed portion,
a width of the first exposed portion along a first direction is greater than that of the second exposed portion along the first direction,
the first direction is parallel to a top surface of the substrate, and
the first development process includes removing the first unexposed portion and the second exposed portion of the upper photoresist layer.

3. The method of claim 2, wherein
the lower photoresist layer includes a third exposed portion, a fourth exposed portion, and a second unexposed portion,
the third exposed portion vertically overlaps with the first exposed portion along a second direction perpendicular to the top surface of the substrate,
the fourth exposed portion vertically overlaps with the second exposed portion along the second direction,
the second unexposed portion vertically overlaps with the first unexposed portion along the second direction, and
the second development process includes removing the fourth exposed portion of the lower photoresist layer.

4. The method of claim 3,
wherein a width of the third exposed portion along the first direction is greater than that of the fourth exposed portion along the first direction.

5. The method of claim 1, further comprising:
performing an etching process using the upper and lower photoresist patterns as etching masks to form a line trench and a contact hole in the etching target layer, wherein
the line trench extends in a first direction parallel to a top surface of the substrate, and
the contact hole extends from a bottom surface of the line trench in a second direction perpendicular to the top surface of the substrate.

6. The method of claim 5, further comprising:
removing the upper and lower photoresist patterns; and
forming a conductive line filling the line trench and a conductive contact filling the contact hole, wherein
the forming the conductive line and the conductive contact comprises:
providing a conductive layer filling the line trench and the contact hole, and
planarizing the conductive layer until a top surface of the etching target layer is exposed.

7. The method of claim 1,
wherein the first photoresist does not contain fluorine.

8. The method of claim 7,
wherein the second photoresist contains fluorine.

9. The method of claim 8,
wherein the first development process is performed using a fluorine-based developer.

10. A method for manufacturing a semiconductor device, the method comprising:
forming a lower photoresist layer on a substrate;
forming an upper photoresist layer on the lower photoresist layer;
performing an exposure process to expose the upper photoresist layer and the lower photoresist layer;
performing a first development process on the upper photoresist layer to form an upper photoresist pattern; and
performing a second development process on the lower photoresist layer to form a lower photoresist pattern, wherein
the lower photoresist layer includes a first photoresist not containing fluorine,
the upper photoresist layer includes a second photoresist containing fluorine, and
the first development process is performed using a fluorine-based developer.

11. The method of claim 10,
wherein the second development process is performed using a developer different from that in the first development process.

12. The method of claim 10, wherein
the first photoresist is positive photoresist, and
the second photoresist is negative photoresist.

13. The method of claim 10, wherein
the upper photoresist layer includes a first exposed portion, a second exposed portion, and a first unexposed portion,
a width of the first exposed portion along a first direction is greater than that of the second exposed portion along the first direction,
the first direction is parallel to a top surface of the substrate,
the first development process includes removing the first unexposed portion and the second exposed portion of the upper photoresist layer, and
the upper photoresist pattern includes the first exposed portion.

14. The method of claim 13, wherein
the lower photoresist layer includes a third exposed portion, a fourth exposed portion, and a second unexposed portion,
the third exposed portion vertically overlaps with the first exposed portion along a second direction perpendicular to the top surface of the substrate,
the fourth exposed portion vertically overlaps with the second exposed portion along the second direction, and
the second unexposed portion vertically overlaps with the first unexposed portion along the second direction.

15. The method of claim 14, wherein
the second development process includes removing the fourth exposed portion of the lower photoresist layer, and
the lower photoresist pattern includes the second unexposed portion and the third exposed portion of the lower photoresist layer.

16. The method of claim 14,
wherein a width of the third exposed portion along the first direction is greater than that of the fourth exposed portion along the first direction.

17. A method for manufacturing a semiconductor device, the method comprising:
forming an etching target layer on a substrate;
forming a lower photoresist layer on the etching target layer;
forming an upper photoresist layer on the lower photoresist layer;
performing a single exposure process to expose the upper photoresist layer and the lower photoresist layer;
performing a first development process on the upper photoresist layer to form an upper photoresist pattern;
performing a second development process on the lower photoresist layer to form a lower photoresist pattern; and
etching the etching target layer by using the upper and lower resist patterns as etching masks, wherein
the upper photoresist layer includes negative photoresist containing fluorine,
the lower photoresist layer includes positive photoresist not containing fluorine, and
the first development process and the second development process are performed using different developers.

18. The method of claim 17,
wherein the first development process includes removing a unexposed portion of the upper photoresist layer using a fluorine-based developer.

19. The method of claim 18, wherein
the upper photoresist layer includes a first exposed portion and a second exposed portion,
a width of the first exposed portion along a first direction is greater than that of the second exposed portion along the first direction,
the first direction is parallel to a top surface of the substrate, and
the first development process further includes removing the second exposed portion of the upper photoresist layer.

20. The method of claim 19, wherein
the lower photoresist layer includes a third exposed portion and a fourth exposed portion,
the third exposed portion vertically overlaps with the first exposed portion along a second direction perpendicular to the top surface of the substrate,
the fourth exposed portion vertically overlaps with the second exposed portion along the second direction, and
the second development process includes removing the fourth exposed portion of the lower photoresist layer.
